(19) United States
(12) Patent Application Publication
(10) Pub. No.: US 2025/0374706 A1
(43) Pub. Date: Dec. 4, 2025

(54) Integrated Configurable Photodetector with Ultra-High Circular Polarization Extinction Ratio and Preparation Method Therefor

(71) Applicant: Shanghai Institute of Technical Physics, CAS, Shanghai (CN)

(72) Inventors: Jing ZHOU, Shanghai (CN); Yonghao BU, Shanghai (CN); Xiaoshuang CHEN, Shanghai (CN); Xiansong REN, Shanghai (CN); Jie DENG, Shanghai (CN); Weida HU, Shanghai (CN); Wei LU, Shanghai (CN)

(21) Appl. No.: 18/731,030

(22) Filed: May 31, 2024

(51) Int. Cl. G01J 4/04; H01L 31/0224; H01L 31/18

(52) U.S. Cl. CPC H10F 77/10

(57) ABSTRACT

An integrated configurable photodetector with an ultra-high circular polarization extinction ratio and a preparation method therefor are provided. The photodetector includes a metal reflective layer, a dielectric layer, an electrode layer, and a two-dimensional material layer. The electrode layer includes symmetrically arranged Z-shaped metallic optical antenna arrays which are respectively integrated with a source electrode and a drain electrode and have opposite chirality. The photodetector operates at zero bias state, and a photo-response is photovoltaic effect, hot electron injection, photo-thermoelectric effect and so on induced by a Schottky junction composed of the source electrode, the drain electrode and the two-dimensional material. By adjusting the distribution of the incident light in the source and drain electrode regions, under specific Circularly polarized light, photocurrents of equal magnitude but opposite directions cancel each other out, resulting in a net output of zero and significantly reducing noise.

### CROSS-REFERENCE TO RELATED APPLICATION

This patent application claims the benefit and priority of Chinese Patent Application No. 202310150843.9 filed with the China National Intellectual Property Administration on Feb. 22, 2023, the disclosure of which is incorporated by reference herein in its entirety as part of the present application.

### TECHNICAL FIELD

The present disclosure relates to the technical field of optoelectronics, and in particular to an integrated configurable photodetector with an ultra-high circular polarization extinction ratio and a preparation method therefor.

### BACKGROUND

Polarization is the main physical quantity of light, and almost all optical science and technique are interested in polarization. Effective polarization detection using miniaturized equipment has always been the goal pursued by people. On-chip polarization detectors has been a promising development direction. In addition to linear polarization detection, circular polarization (or optical ellipticity) detection is essential for chiral molecular recognition, magnetic field sensing, quantum communication, and cryptography.

The traditional solution depends on an external optical system including a polarizer and a wave plate, and the complexity and size of an optical ellipticity detector are obvious. Although the metasurface, as a planar optical device, can potentially reduce the occupied area of the optical ellipticity detector by replacing the traditional polarizer or wave plate, the problems of energy loss and alignment difficulty cannot be avoided. Although some studies have proposed materials with circular dichroism or circular photocurrent effect for optical ellipticity detection without optical lenses, these materials are not common, and have extremely low optical ellipticity discrimination ability. In this case, the direct integration of a plasma chiral structure and a photoelectric detection material for achieving a compact optical ellipticity detector is an eye-catching and in-depth research direction. The integrated plasma chiral structure not only can provide circular polarization discrimination, but also can enhance the absorptivity of the detection material through enhanced local fields. However, the biggest problem is the lack of light ellipticity discrimination. Circular polarization extinction ratio (CPER) is defined as a ratio of photo-responses produced when the photodetector operates under the incidence of circularly polarized light in two different rotation direction, and the ratio is greater than 1. For the traditional circular polarizer, the parameter is usually higher than 1000, but the CPER of a metasurface, or a detector made of materials with circular dichroism or circular photocurrent effect alone, is usually lower than 5, and thus the response of circularly polarized light to non-target rotation direction cannot be effectively suppressed.

### SUMMARY

An objective of the present disclosure is to provide an integrated configurable photodetector with an ultra-high circular polarization extinction ratio and a preparation method therefor, so as to solve the problem of low circular polarization extinction ratio in on-chip circular polarization detection,

To achieve the objective above, the present disclosure employs the following technical solution:

An integrated configurable photodetector with an ultra-high circular polarization extinction ratio includes a bottom substrate layer, a metal reflective layer, a dielectric layer, an electrode layer, and a two-dimensional material layer from bottom to top. The electrode layer and the two-dimensional material layer can be arranged in a reverse order. The electrode layer includes a metallic two-dimensional chiral metamaterial integrated in a source electrode and a metallic two-dimensional chiral metamaterial integrated in a drain electrode, which are symmetrically arranged. The metallic two-dimensional chiral metamaterial integrated in the source electrode and the metallic two-dimensional chiral metamaterial integrated in the drain electrode are Z-shaped metallic optical antenna arrays with opposite chiral structures.

When the integrated configurable photodetector with the ultra-high circular polarization extinction ratio operates at zero bias state, a photo-response is photovoltaic effect, hot electron injection, and photo-thermoelectric effect induced by a Schottky junction composed of the source electrode, the drain electrode and the two-dimensional material. An intensity ratio of incident light of two Z-shaped metallic optical antenna arrays at the source electrode and the drain electrode is configured by moving an incident light spot, and thus the source electrode and the drain electrode can generate photocurrents with a same magnitude but opposite directions under irradiation of circularly polarized light in any specific rotation direction, a net photocurrent output from the photodetector is zero, and a e noise is reduced by 1 to 2 orders of magnitude. The photodetector continues to stably output a photocurrent under irradiation of a circularly polarized light in another rotation direction.

Alternatively, the bottom substrate layer is a support layer of the photodetector.

The bottom substrate layer is made of a semiconductor process base material, and the semiconductor process base material includes Si, GaAs, and GaN.

Alternatively, the thickness of the metal reflective layer is not less than twice a skin depth of electromagnetic waves in the metal reflective layer.

Alternatively, the dielectric layer is a medium with a transparent operating band.

A thickness of the dielectric layer is less than a quarter of a detection wavelength.

Alternatively, the electrode layer includes the source electrode, the drain electrode, and the metallic two-dimensional chiral metamaterials.

The source electrode and the drain electrode are symmetrically arranged, and a channel is provided between the source electrode and the drain electrode.

The metallic two-dimensional chiral metamaterials are integrated in the source electrode and the drain electrode, respectively.

Alternatively, the two-dimensional material is arranged on the metallic two-dimensional chiral metamaterial, and the two-dimensional material is used to cross the channel and electrically connect the source electrode and the drain electrode.

Alternatively, a thickness of the electrode layer is not less than twice a skin depth of electromagnetic waves in the electrode layer.

A preparation method for an integrated configurable photodetector with an ultra-high circular polarization extinction ratio includes:
growing a metal reflective layer on a bottom substrate layer using an electron beam evaporation or thermal evaporation technique;
growing a dielectric layer on a surface of the metal reflective layer by an atomic layer deposition, the electron beam evaporation technique and a magnetron sputtering;
defining a pattern on a surface of the dielectric layer using an electron beam lithography technique, depositing metal using the electron beam evaporation technique, and obtaining a required electrode layer by a lift-off process, where the electrode layer comprises a metallic two-dimensional chiral metamaterial integrated in a source electrode and a metallic two-dimensional chiral metamaterial integrated in a drain electrode, which are symmetrically arranged; and the metallic two-dimensional chiral metamaterial integrated in the source electrode and the metallic two-dimensional chiral metamaterial integrated in the drain electrode are Z-shaped metallic optical antenna arrays with opposite chiral structures;
obtaining a two-dimensional material from a single crystal sample using a mechanical exfoliation method, or obtaining the two-dimensional material using growth means, and transferring the two-dimensional material onto the electrode layer using a dry transfer technique to cross a channel between the source electrode and the drain electrode and to electrically connect the source electrode and the drain electrode, where the growth techniques such as chemical vapor deposition (CVD) or physical vapor deposition (PVD).

According to specific embodiments provided by the present disclosure, the present disclosure provides the following technical effects: an integrated configurable photodetector with an ultra-high circular polarization extinction ratio and a preparation method therefor are provided. When the integrated configurable photodetector with an ultra-high circular polarization extinction ratio operates at zero bias state, a photoresponse is photovoltaic effect, hot electron injection, and photo-thermoelectric effect induced by a Schottky junction composed of the source electrode, the drain electrode and a two-dimensional material. An intensity ratio of incident light of the two Z-shaped metallic optical antenna arrays at the source electrode and the drain electrode is configured by moving an incident light spot. Under the irradiation of circularly polarized light in a certain direction, the photocurrents which are generated by the source electrode and the drain electrode and have the same magnitude but opposite directions can cancel each other, thus making a net photocurrent output by the whole detector zero, and reducing the noise by 1 to 2 orders of magnitude. Under the irradiation of circularly polarized light in another direction, a photocurrent generated by the electrode at one end is greater than that generated by the electrode at the other end, the whole detector continues to stably output a certain photocurrent. The detector shows ultra-high circularly polarized light discrimination capacity, and can obtain an ultra-high extinction ratio in a suitable wavelength range.

### BRIEF DESCRIPTION OF THE DRAWINGS

To describe the technical solutions of the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a schematic diagram of a photodetector structure according to the present disclosure;

FIG. 2 is a side view of an XZ plane of a photodetector structure according to the present disclosure;

FIG. 3 is a top view of a photodetector structure according to the present disclosure;

FIG. 4 is a schematic structural diagram of a Z-shaped metallic optical antenna unit with selective response to left-handed circularly polarized light in a photodetector according to the present disclosure;

FIG. 5 is a diagram showing absorption spectra of left-handed circularly polarized light and right-handed circularly polarized light of a Z-shaped metallic optical antenna array with selective response to left-handed circularly polarized light in a photodetector according to the present disclosure;

FIG. 6 is a spectrum diagram of photoresponses of left-handed circularly polarized light and right-handed circularly polarized light of a Z-shaped metallic optical antenna array with selective response to left-handed circularly polarized light in a photodetector according to the present disclosure;

FIG. 7 is a diagram showing a relationship between CPER of a Z-shaped metallic optical antenna array with selective response to left-handed circularly polarized light and a wavelength of detection light in a photodetector according to the present disclosure;

FIG. 8 is a diagram showing a relationship between a photocurrent and a half wave plate rotation angle when a photodetector according to the present disclosure configured to have a selective response to left-handed circularly polarized light operates at a wavelength of 1550 nm.

In the drawings:
1-bottom substrate layer; 2-metal reflective layer; 3-dielectric layer; 4-electrode layer; 5-two-dimensional material layer.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by a person of ordinary skill in the art based on the embodiments of the present disclosure without creative efforts shall fall within the protection scope of the present disclosure.

An objective of the present disclosure is to provide an integrated configurable photodetector with an ultra-high circular polarization extinction ratio and a preparation method therefor. The integrated configurable photodetector with an ultra-high circular polarization extinction ratio has ultra-high circularly polarized light discrimination capacity, and can obtain an ultra-high extinction ratio in a suitable wavelength range.

In order to make the objectives, technical solutions and advantages of the present disclosure more clearly, the present disclosure is further described in detail below with reference to the accompanying drawings and the embodiments.

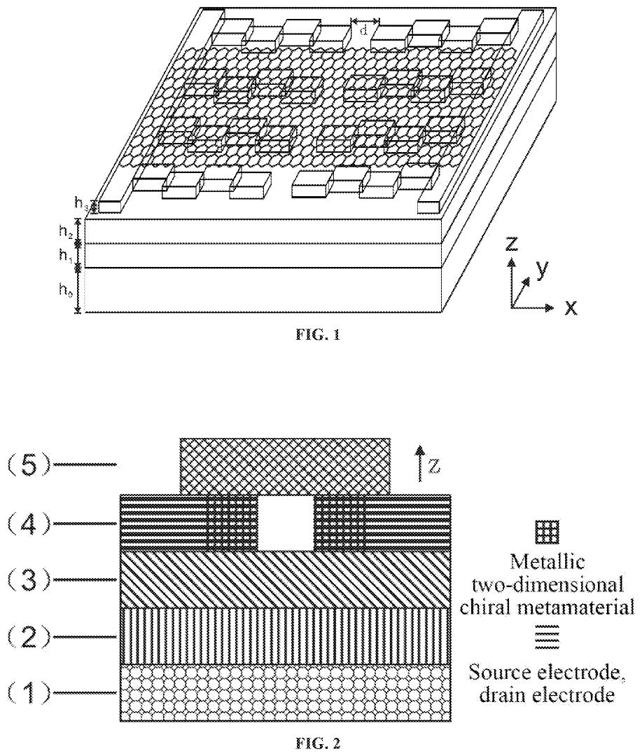

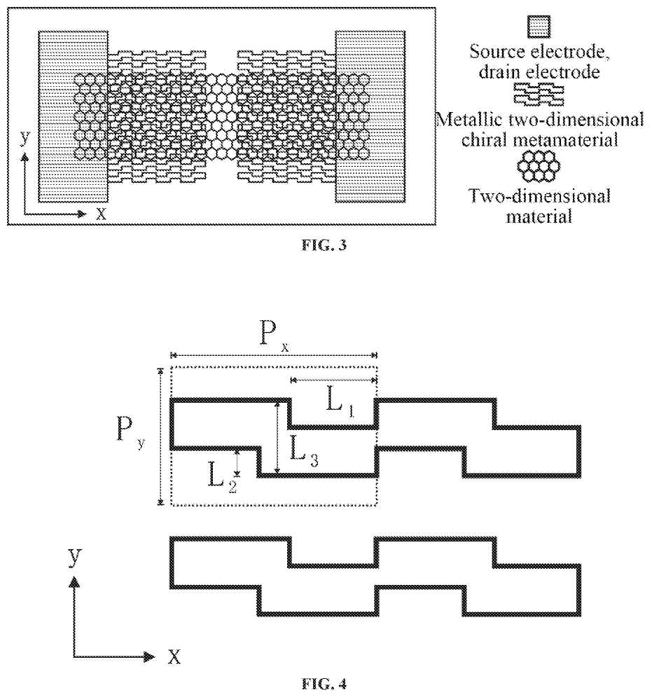

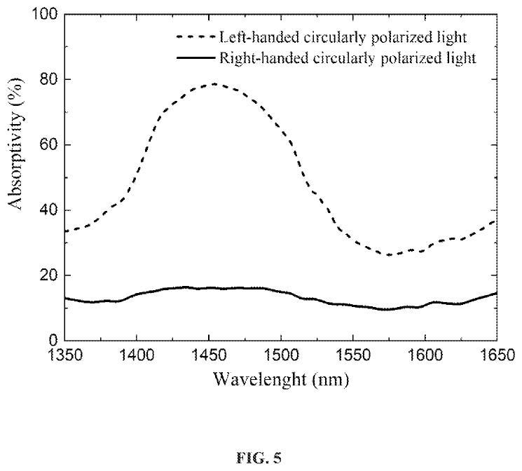

As shown in FIG. 1 to FIG. 4, an integrated configurable photodetector with an ultra-high circular polarization extinction ratio includes a bottom substrate layer 1, a metal reflective layer 2, a dielectric layer 3, an electrode layer 4, and a two-dimensional material layer 5 from bottom to top. The electrode layer 4 and the two-dimensional material layer 5 can be arranged in a reverse order. The electrode layer 4 includes metallic two-dimensional chiral metamaterials which are symmetrically arranged and integrated in a source electrode and a drain electrode, respectively. The metallic two-dimensional chiral metamaterial integrated in the source electrode and the metallic two-dimensional chiral metamaterial integrated in the drain electrode are Z-shaped metallic optical antenna arrays with opposite chiral structures. When the integrated configurable photodetector with an ultra-high circular polarization extinction ratio operates at zero bias state, a photo-response is photovoltaic effect, hot electron injection, and photo-thermoelectric effect induced by a Schottky junction composed of the source electrode, the drain electrode and a two-dimensional material; an intensity ratio of incident light of the two Z-shaped metallic optical antenna arrays at the source electrode and the drain electrode is configured by moving an incident light spot, and thus the source electrode and the drain electrode can generate photocurrents with the same magnitude but opposite directions under the irradiation of circularly polarized light in any specific rotation direction, a net output photocurrent is zero, and the noise is reduced by 1 to 2 orders of magnitude. The photodetector continues to stably output a photocurrent under the irradiation of circularly polarized light in another rotation direction.

In actual application, the bottom substrate layer 1 with a thickness of h₀ is a support layer of the device, which is made of, but not limited to, Si, GaAs, GaN and other conventional semiconductor process base materials,

The metal reflective layer 2 is a layer of complete metal reflective layer 2 with a thickness of h₁, and h₁ is not less than twice a skin depth of electromagnetic waves in the metal. The metal reflective layer 2 is made of metal with high conductivity, including, but not limited to, gold, silver, aluminum, or alloy thereof.

The dielectric layer 3 is a medium with a thickness of h₂ and with a transparent operating band, including, but not limited to, Al₂O₃, SiO₂, MgF₂, ZnS, HfO₂, and the like. The thickness h₂ is less than a quarter of a detection wavelength.

The electrode layer 4 is a layer of high-conductivity metal with a thickness of h₃, the metal includes, but is not limited to, gold, silver, aluminum, or alloy thereof, and h₃ is not less than twice a skin depth of electromagnetic waves in the metal. Z-shaped metallic optical antennas with opposite chiral structures are integrated in the source electrode region and the drain electrode region, respectively. The size of a cell structure of the Z-typed metallic optical antenna is determined by Pₓ (a single cycle length in x direction), P_{y} (a single cycle length in y direction), L₁ (a length of an air medium, which is less than the cycle length range within the single cycle in x direction), L₂ (a length of an air medium, which is less than the cycle length range within the single cycle in y direction) and L₃ (metal length within the single cycle in the y direction), where L₂ is less than L₃. L₃ is a quarter to a half of P_{y}, and L₁ is less than Pₓ/2. Both sides of the Z-shaped metallic optical antenna regions with mutual chirality are connected to the source electrode and the drain electrode, respectively, and a channel between the two regions has a width of d, which is not more than 4 μm. The electrode layer 4 is a source electrode layer and a drain electrode layer integrated with the metallic two-dimensional chiral metamaterial.

The two-dimensional material layer 5 is a material with atomic longitudinal scale, including, but not limited to, two-dimensional semiconductors, and a two-dimensional semi-metallic material. There is Van Der Waals bonding force for binding between layers, and no dangling bond exists. The material includes, but is not limited to, Graphene, hBN, MoS₂, blackphosphorous, WS₂, etc.

In addition, in this structure, the order of the electrode layer 4 and the two-dimensional material layer 5 are not fixed, and the electrode layer 4 may be above the two-dimensional material.

For a chiral Z-shaped metallic optical antenna, under the irradiation of circularly polarized light of a target to be detected, the Z-typed metallic optical antenna excites a surface plasmon polariton mode near a metallic optical antenna, and most of the incident light is efficiently coupled into this surface plasmon polariton mode. For non-target circularly polarized light, the surface plasmon polariton mode near the metallic optical antenna cannot be effectively excited, and an optical field in the composite structure is very limited. Therefore, when an optical field of the target circularly polarized light is localized near the metallic chiral optical antenna, an optical field at the two-dimensional material is enhanced, and the responsivity of the detector is improved.

When the detection mode of the detector is hot electron injection, photovoltaic response and other self-driven response modes, under the excitation of a light source, the source electrode and the drain electrode can generate photocurrents in a specific direction. As a local region of the source electrode is provided with a Z-shaped metallic optical antenna which is chirally symmetric with the drain electrode, the source electrode can absorb the circularly polarized light opposite to a characteristic rotation absorbed by the drain electrode, and generate a directional photocurrent opposite to a direction of the drain electrode.

By configuring optical power distribution in the source electrode region and the drain electrode region (depending on the CPER of the Z-shaped metallic optical antenna array on one side), the photocurrents generated by the source electrode and the drain electrode in opposite directions cancel each other under the irradiation of circularly polarized light in a certain direction, and the photocurrent output by the whole detector is reduced to the noise level, which is close to zero. Under the irradiation of circularly polarized light in another direction, a photocurrent generated by the electrode at one end is greater than that generated by the electrode at the other end, the whole detector continues to stably output a certain photocurrent. The detector shows ultra-high circularly polarized light discrimination capacity.

A preparation method for an integrated configurable photodetector with an ultra-high circular polarization extinction ratio includes the following steps:
growing a metal reflective layer 2 on a bottom substrate layer 1 using an electron beam evaporation or thermal evaporation technique;
growing a dielectric layer 3 on a surface of the metal reflective layer 2 by atomic layer deposition;
defining a pattern on a surface of the dielectric layer 3 using an electron beam lithography technique, depositing metal using the electron beam evaporation technique, and obtaining a required electrode layer 4 by a lift-off process, where the electrode layer 4 includes a metallic two-dimensional chiral metamaterial integrated in a source electrode and a metallic two-dimensional chiral metamaterial integrated in a drain electrode, which are symmetrically arranged; and the metallic two-dimensional chiral metamaterial integrated in the source electrode and the metallic two-dimensional chiral metamaterial integrated in the drain electrode are Z-shaped metallic optical antenna arrays with opposite chiral structures;
obtaining a two-dimensional material from a single crystal sample using a mechanical exfoliation method, or obtaining the two-dimensional material using growth means, and transferring the two-dimensional material onto the electrode layer 4 using a dry transfer technique to cross a channel between the source electrode and the drain electrode and to electrically connect the source electrode and the drain electrode, where the growth means include chemical meteorological deposition, and physical vapor deposition.

In this embodiment, a detection target wavelength is 1550 nm. Firstly, it is obtained through electromagnetic simulation optimization that the metal reflective layer 2 is made of Au, the dielectric layer 3 is made of Al₂O₃, and the electrode layer 4 is made of Ti and Au. The structural dimensions of the metallic two-dimensional chiral metamaterial are Pₓ=780 nm, P_{y}=550 nm, L₁=280 nm, L₂=90 nm, L₃=220 nm and h₃=30 nm (Ti is 3 nm, Au is 27 nm). A channel between the source electrode region and the drain electrode region is 4 μm, and the size of the metallic chiral optical antenna region on one side of the source and drain electrode regions is 36 μm×33 μm. The Z-shaped metallic optical antenna array at the source electrode region is designed to absorb left-handed circularly polarized light obviously.

In this embodiment, a substrate material is a single-throw dioxygen Si substrate with a thickness of 500 μm, and the thickness of a SiO2 oxide layer on the surface of the substrate material is 285 nm. The material Au of the metal reflective layer 2 is grew using an electron beam evaporation technique, and has a thickness of 100 nm. The material Al₂O₃ of the dielectric layer 3 has a thickness of 200 nm.

In order to improve the contact between the Au and the medium material, Ti is grew on interfaces, in contact with of SiO₂ and Al₂O₃, of the metal reflective layer 2 as adhesive layers, with thicknesses of 10 nm and 5 nm, respectively. The source and drain electrode layer 4 integrated with the metallic chiral two-dimensional metamaterials are Ti and Au, which have thicknesses of 3 nm and 27 nm, respectively.

In this embodiment, the material type of the two-dimensional material layer 5 is MoS₂ and the thickness is 8 nm. MoS₂ obtained by mechanical exfoliation is transferred to the electrode layer 4 by polycarbonate (PC) and polydimethylsiloxane (PDMS) and crosses the channel. Residual polycarbonate is removed using a chloroform solution.

MoS₂ is in contact with Au to form a Schottky junction, and a self-driven photocurrent at the junction is attributed to hot electron injection induced by plasma resonance. Referring to FIG. 5 to FIG. 7, in the wavelength range of 1400 nm to 1600 nm, the absorption and photo-response of the Z-typed metallic optical antenna array in the source electrode region have obvious differences in absorption and photo-response for the left-handed circularly polarized light and the right-handed circularly polarized light, and the CPER value at 1550 nm is 3.28.

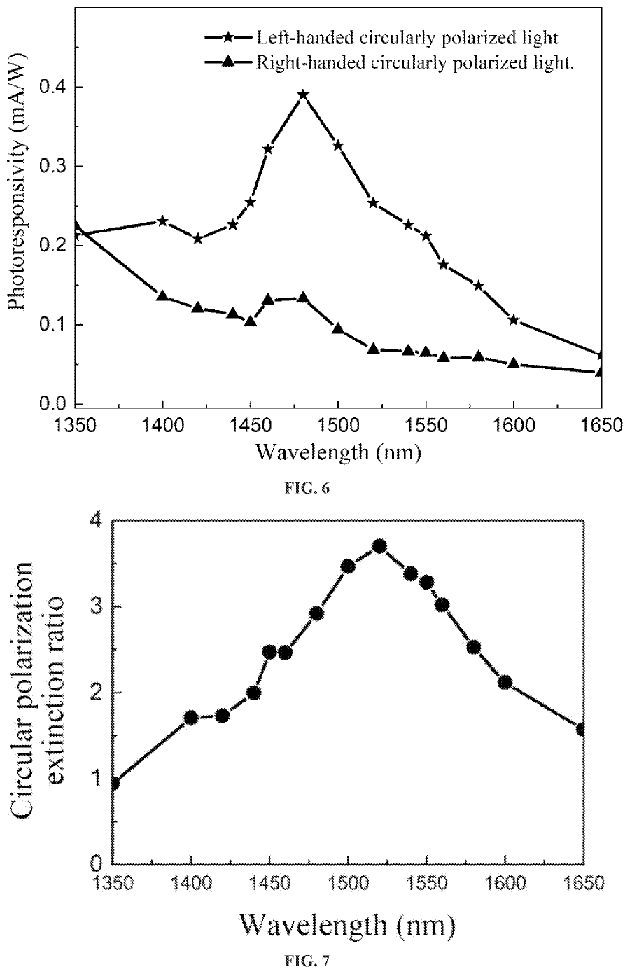

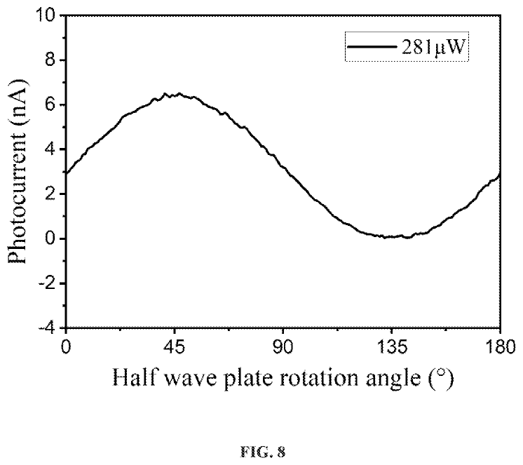

Referring to FIG. 8, combined with experimental results in FIG. 6, in the test configuration, a wavelength of the incident light is 1550 nm, and the optical power is 281 μW. The incident light irradiates a surface of the detector after passing through a linear polarizer, a half wave plate and a quarter wave plate in sequence, and a fast axis direction of the wave plate and a polarization direction of the linearly polarized light are both perpendicular to in-plane x axis. A ratio of the optical power allocated by the source electrode to the optical power allocated by the drain electrode is adjusted to 1: 3.28. A photocurrent of the detector is 7 nA when the left-handed circularly polarized light enters, and a photocurrent is close to 0 nA when the right-handed circularly polarized light enters. By using this detection method, the detector shows a circular polarization extinction ratio that tends to infinity.

Similarly, with reference to FIG. 7, the optical power allocation of the source electrode and the drain electrode of the detector can be reasonably adjusted within a suitable wavelength range, and the detector can be configured to be basically unresponsive to the left-handed circularly polarized light or the right-handed circularly polarized light within the detection wavelength, thus obtaining an ultra-high polarization extinction ratio.

The present disclosure at least includes the following three advantages:
1. By configuring the intensity ratio of incident light of the two Z-shaped metallic optical antenna array areas at the source electrode and the drain electrode, a photocurrent output by the detector can be close to zero under the incident of rotary light in a certain specific rotation direction, while the detector can continuously and stably output a photocurrent with a certain value under the incident of the rotary light in another rotation direction. Therefore, the ultra-high extinction ratio can be obtained within a suitable wavelength range, and the detector has ultra-high discrimination capacity for the left-handed circularly polarized light or right-handed circularly polarized light.
2. By exciting the surface plasmon polariton mode, a local strong optical field which fully overlaps with a quantum well layer in space is generated, such that the absorptivity and quantum efficiency of the two-dimensional material are improved on the basis of achieving the discrimination of circular polarization with high extinction ratio.
3. There is no need of independent optical elements in the detector, and the detector has the advantages of high integration, easy preparation, small volume, high stability and reliability, and high universality, for example, the size of the metallic optical antenna can be changed, a target detection wavelength of the detector can be adjusted arbitrarily; the Z-shaped metallic optical antenna can be arbitrarily changed as other metallic optical micro-nano structures, thus detecting a required polarization state (such as linearly polarized light); the material of the detection channel can be changed to adapt to self-driven response modes such as a photovoltaic response, photo-thermal response and so on.

Various embodiments in this specification are described in a progressive way, and each embodiment focuses on the differences from other embodiments, so it is only necessary to refer to the same and similar parts between each embodiment.

Specific examples are used herein for illustration of the principles and embodiments of the present disclosure. The description of the embodiments is merely used to help illustrate the method and its core principles of the present disclosure. In addition, a person of ordinary skill in the art can make various modifications in terms of specific embodiments and scope of application in accordance with the teachings of the present disclosure. In conclusion, the content of this specification shall not be construed as a limitation to the present disclosure.

What is claimed is:

1. An integrated configurable photodetector with an ultra-high circular polarization extinction ratio, comprising a bottom substrate layer, a metal reflective layer, a dielectric layer, an electrode layer, and a two-dimensional material layer from bottom to top, wherein the electrode layer and the two-dimensional material layer are able to be arranged in a reverse order; the electrode layer comprises a metallic two-dimensional chiral metamaterial integrated in a source electrode and a metallic two-dimensional chiral metamaterial integrated in a drain electrode, which are symmetrically arranged; the metallic two-dimensional chiral metamaterial integrated in the source electrode and the metallic two-dimensional chiral metamaterial integrated in the drain electrode are Z-shaped metallic optical antenna arrays with opposite chiral structures;
when the integrated configurable photodetector with the ultra-high circular polarization extinction ratio operates at zero bias state, a photo-response is photovoltaic effect, hot electron injection, and photo-thermoelectric effect induced by a Schottky junction composed of the source electrode, the drain electrode and the two-dimensional material; an intensity ratio of incident light of two Z-shaped metallic optical antenna arrays at the source electrode and the drain electrode is configured by moving an incident light spot, and thus the source electrode and the drain electrode are able to generate photocurrents with a same magnitude but opposite directions under irradiation of a circularly polarized light in any specific rotation direction, a net photocurrent output from the photodetector is zero, and noise is reduced by 1 to 2 orders of magnitude; and the photodetector continues to stably output a photocurrent under irradiation of a circularly polarized light in another rotation direction.

2. The integrated configurable photodetector with the ultra-high circular polarization extinction ratio according to claim 1, wherein the bottom substrate layer is a support layer of the photodetector;
the bottom substrate layer is made of a semiconductor process base material, and the semiconductor process base material comprises Si, GaAs, and GaN.

3. The integrated configurable photodetector with the ultra-high circular polarization extinction ratio according to claim 1, wherein a thickness of the metal reflective layer is not less than twice a skin depth of electromagnetic waves in the metal reflective layer.

4. The integrated configurable photodetector with the ultra-high circular polarization extinction ratio according to claim 1, wherein the dielectric layer is a medium with a transparent operating band; and
a thickness of the dielectric layer is less than a quarter of a detection wavelength.

5. The integrated configurable photodetector with the ultra-high circular polarization extinction ratio according to claim 1, wherein the electrode layer comprises the source electrode, the drain electrode, and the metallic two-dimensional chiral metamaterials;
the source electrode and the drain electrode are symmetrically arranged, and a channel is provided between the source electrode and the drain electrode; and
the metallic two-dimensional chiral metamaterials are integrated in the source electrode and the drain electrode, respectively.

6. The photodetector according to claim 5, wherein the two-dimensional material is arranged on the metallic two-dimensional chiral metamaterial, and the two-dimensional material is used to cross the channel and electrically connect the source electrode and the drain electrode.

7. The photodetector according to claim 5, wherein a thickness of the electrode layer is not less than twice a skin depth of electromagnetic waves in the electrode layer.

8. A preparation method for an integrated configurable photodetector with an ultra-high circular polarization extinction ratio, comprising:
growing a metal reflective layer on a bottom substrate layer using an electron beam evaporation technique or a thermal evaporation technique;
growing a dielectric layer on a surface of the metal reflective layer by atomic layer deposition, the electron beam evaporation and magnetron sputtering;
defining a pattern on a surface of the dielectric layer using electron beam lithography technique, depositing metal using the electron beam evaporation technique, and obtaining a required electrode layer by a lift-off process, wherein the electrode layer comprises a metallic two-dimensional chiral metamaterial integrated in a source electrode and a metallic two-dimensional chiral metamaterial integrated in a drain electrode, which are symmetrically arranged; and the metallic two-dimensional chiral metamaterial integrated in the source electrode and the metallic two-dimensional chiral metamaterial integrated in the drain electrode are Z-shaped metallic optical antenna arrays with opposite chiral structures; and
obtaining two-dimensional materials from a single crystal sample using a mechanical exfoliation method, or obtaining the two-dimensional material using growth means, and transferring the two-dimensional material onto the electrode layer using a dry transfer technique to cross a channel between the source electrode and the drain electrode and to electrically connect the source electrode and the drain electrode, the growth methods include chemical vapor deposition and physical vapor deposition.
